(19) United States
(12) Patent Application Publication
(10) Pub. No.: US 2022/0415609 A1
(43) Pub. Date: Dec. 29, 2022

(54) Scanning Electron Microscope

(71) Applicant: Hitachi High-Tech Corporation, Minato-ku, Tokyo (JP)

(72) Inventors: Takumi UEZONO, Tokyo (JP); Tadanobu TOBA, Tokyo (JP); Hironori ITABASHI, Tokyo (JP); Masato KAMIO, Tokyo (JP)

(21) Appl. No.: 17/778,320

(22) PCT Filed: Nov. 21, 2019
(86) PCT No.: PCT/JP2019/045622

§ 371 Date: May 19, 2022

(51) Int. Cl. H01J 37/26; H01J 37/285

(52) U.S. Cl. CPC H01J 37/261; H01J 37/285

(57) ABSTRACT

A scanning electron microscope includes a management computer that generates an irradiation control command of an electron beam, a control block that generates a control signal on the basis of the irradiation control command, and a beam irradiation control device that controls an irradiation direction of the electron beam on the basis of the control signal. The management computer generates the irradiation control command on the basis of a scan type selected by a user and scan parameters set by the use

### TECHNICAL FIELD

The present invention relates to a scanning electron microscope.

### BACKGROUND ART

A scanning electron microscope (SEM) is used in a wide range of fields such as semiconductor devices, electronics, advanced materials, biology, and pharmaceuticals. The scanning electron microscope is required to have high resolution, improved image quality and usability, lower price, high sophistication, performance that can withstand observation of various samples under various conditions, and the like.

In the current scanning electron microscope, an SEM user generally selects an observation condition suitable for observation from a plurality of observation conditions preset by a device manufacturer and observes a sample. Further, even if the observation conditions can be changed, only a part of the observation conditions can be changed, and a basic scanning direction and scanning order of the SEM cannot be changed.

For example, JP-A-2018-133243 (PTL 1) discloses a method of adjusting an irradiation area of an electron beam in an electron beam irradiation device that deflects the electron beam with a deflector to irradiate an irradiation target with the electron beam. Specifically, adjusting the irradiation area of the electron beam includes an electron beam irradiation step of irradiating the electron beam while changing an irradiation position with respect to an adjustment plate that detects a current corresponding to the irradiated electron beam by controlling the deflector on the basis of an electron beam irradiation recipe, a current acquisition step of acquiring the current detected from the adjustment plate, an image formation step of forming image data corresponding to the acquired current value, a determination step of determining whether or not the irradiation area of the electron beam is appropriate on the basis of the formed image data, and a recipe update step of updating the electron beam irradiation recipe when it is determined that the irradiation area is inappropriate.

### CITATION LIST

### Patent Literature

PTL 1: JP-A-2018-133243

### SUMMARY OF INVENTION

### Technical Problem

As already mentioned, the scanning electron microscope is required to have performance that can withstand various conditions for various samples. However, due to time constraints, electron beam control is realized by hardware, and the sample can be observed only under a preset scanning condition. When acquiring an image under a new condition, since the hardware needs to be modified, the turn around time (TAT) becomes long.

Therefore, an object of the present invention is to provide a scanning electron microscope capable of observing a sample under desired scanning condition while suppressing an increase in TAT.

### Solution to Problem

A brief description of representative inventions of the inventions disclosed in the present application is as follows.

A scanning electron microscope according to a representative embodiment of the present invention includes a management computer that generates an irradiation control command of an electron beam, a control block that generates a control signal on the basis of the irradiation control command, and a beam irradiation control device that controls an irradiation direction of the electron beam on the basis of the control signal. The management computer generates the irradiation control command on the basis of a scan type selected by a user and scan parameters set by the user.

### Advantageous Effects of Invention

A brief description of the effects obtained by the representative invention of the inventions disclosed in the present application is as follows.

That is, according to the representative embodiment of the present invention, it is possible to observe the sample under the desired scanning condition while suppressing the increase in TAT.

### BRIEF DESCRIPTION OF DRAWINGS

FIG. 1 is a diagram illustrating an example of a configuration of a scanning electron microscope according to Embodiment 1 of the present invention.

FIG. 2 is a diagram illustratively describing an irradiation control command and a corresponding scan waveform in comparison with each other.

FIG. 3 is a diagram illustratively describing a waveform combination command and a corresponding scan waveform in comparison with each other.

FIG. 4 is a diagram illustrating an example of a command template.

FIG. 5 is a diagram illustrating an example of a configuration of a scanning electron microscope according to Embodiment 2 of the present invention.

FIG. 6 is a diagram illustrating an example of a configuration of a scanning electron microscope according to Embodiment 3 of the present invention.

### Description of Embodiments

Hereinafter, embodiments of the present invention will be described with reference to the drawings. Each embodiment described below is an example for implementing the present invention, and does not limit a technical scope of the present invention. In examples, members having the same function are designated by the same reference numerals, and the repeated description thereof will be omitted unless it is particularly needed.

### Embodiment 1

### <Configuration of Scanning Electron Microscope>

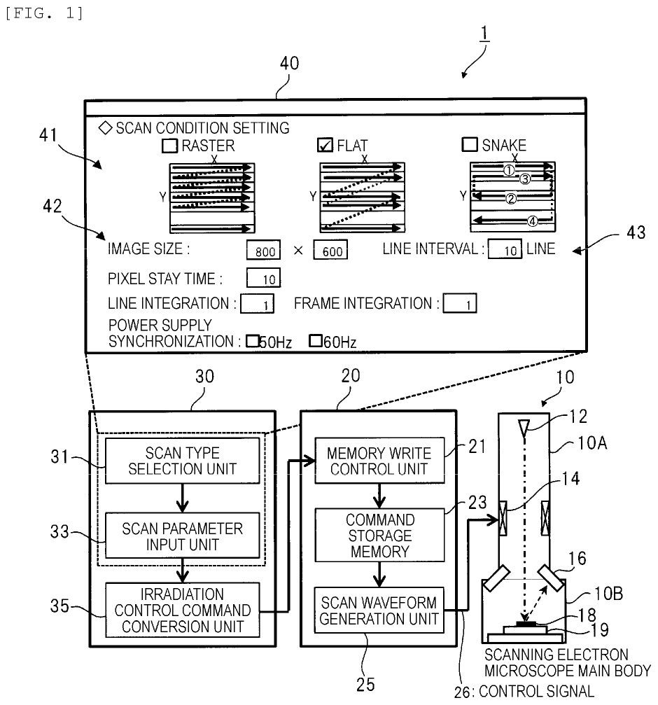

FIG. 1 is a diagram illustrating an example of a configuration of a scanning electron microscope according to Embodiment 1 of the present invention. A scanning electron microscope 1 of FIG. 1 includes a scanning electron microscope main body 10, a control block 20, and a management computer 30.

The scanning electron microscope main body 10 has a configuration in which a lens barrel 10A is placed in a sample chamber 10B in which a sample for inspection is housed. The lens barrel 10A houses an electron gun 12 that irradiates an electron beam toward the sample 18, a beam irradiation control device 14 that controls an irradiation direction of the electron beam, and the like. The beam irradiation control device 14 controls the electron beam on the basis of a control signal transmitted from the control block 20. The beam irradiation control device 14 includes, for example, a deflector, a diaphragm, an objective lens, and the like (all of which are not illustrated). A method of controlling the electron beam by the beam irradiation control device 14 will be described in detail later.

Further, the lens barrel 10A houses a detector 16 that detects secondary electrons emitted from the sample 18 by irradiation with the electron beam and outputs a detection signal on the basis of the secondary electrons, and the like. The secondary electrons referred to here also include reflected electrons and the like. On the basis of the detection signal from the detector 16, an inspection image such as an SEM image is generated, a size of the sample 18 is measured, the electrical characteristics are measured, and the like. The processing based on the detection signal is executed by an arithmetic circuit (not illustrated) and the like. The detector 16 may be installed in the sample chamber 10B. Further, a plurality of detectors 16 may be separately installed in the lens barrel 10A and the sample chamber 10B.

The sample chamber 10B houses a stage 19, the sample 18, and the like. The sample 18 is placed on the stage 19. The sample 18 is, for example, a semiconductor device, a semiconductor wafer including a plurality of semiconductor devices, and the like. The stage 19 is provided with a stage drive mechanism (not illustrated). By the stage driving mechanism, the sample 18 can be moved in the sample chamber 10B.

As illustrated in FIG. 1, the management computer 30 includes a scan type selection unit 31, a scan parameter input unit 33, and an irradiation control command conversion unit 35. The scan type selection unit 31, the scan parameter input unit 33, and the irradiation control command conversion unit 35 are realized by executing a program by a processor such as a CPU. Further, the scan type selection unit 31, the scan parameter input unit 33, and the irradiation control command conversion unit 35 may be configured by, for example, hardware such as a field-programmable gate array (FPGA) or an application specific integrated circuit (ASIC), or may be configured by combining hardware and software.

The scan type selection unit 31 is a functional block that selects a scan type of the electron beam. The scan parameter input unit 33 is a functional block that performs setting processing of parameters of the scan type (scan parameters) selected by the scan type selection unit 31.

Each processing by the scan type selection unit 31 and the scan parameter input unit 33 is performed on the basis of an operation of a GUI screen (input screen) 40 as illustrated in FIG. 1, for example. The GUI screen 40 is displayed on a display (not illustrated) and receives an input operation and touch operation by an input device such as a keyboard and a mouse by a user.

The GUI screen 40 includes, for example, a scan type selection area 41 where the scan type is selected, a common parameter setting area 42 in which common parameters are set in common among all scan types, an individual parameter setting area 43 for setting individual parameters for each scan type. The scan type selection area 41 corresponds to the scan type selection unit 31. The common parameter setting area 42 and the individual parameter setting area 43 correspond to the scan parameter input unit 33. The selection of the scan type and setting of the parameter on the GUI screen 40 are performed by checking a corresponding item, inputting a numerical value of the parameter, and the like.

Examples of the scan type selected in the scan type selection area 41 include a “raster”, a “flat”, a “snake”, and the like. The “raster” is a scan type that sequentially scans adjacent lines without skipping a line. The “flat” is a scan type in which lines are sequentially scanned while skipping the line by a line interval set in the individual parameter setting area 43.

The “snake” is, for example, a scan type in which scanning from left to right and scanning from right to left are alternately performed. In the example of FIG. 1, when scanning for one line from left to right is performed, an operation of scanning from right to left for another line at intervals of several lines and then scanning from left to right for still another line is repeated. Specifically, after scanning from left to right, scanning is performed from right to left with respect to a line below the scanned line in the figure. Then, when scanning from right to left is performed, scanning is performed from left to right with respect to a line above the scanned line in the figure.

In the “raster” and the “flat”, scanning directions in respective lines are the same. In contrast, in the “snake”, the scanning directions are alternately switched. Although FIG. 1 illustrates a case where the scanning direction is the X-direction, the scanning direction may be the Y-direction.

The common parameters set in the common parameter setting area 42 include, for example, the size (image size) of the inspection image acquired by the scanning electron microscope, the time (pixel stay time) during which the electron beam is irradiated to an area corresponding to each pixel of the inspection image, selection of synchronization (power supply synchronization) between a period of the electron beam and a period of an AC power supply input to the scanning electron microscope, and the like. Further, the “line integration” illustrated in FIG. 1 indicates, for example, the number of times of scanning to the same line, and the “frame integration” indicates the number of times of scanning to the entire area corresponding to the image size.

The individual parameters set in the individual parameter setting area 43 include, for example, the “line interval” in the beam operation method “flat” and the like. The “line interval” is a value that prescribes an interval between a line from which image data is acquired and a line from which the image data is acquired next when the image data is acquired for each line. That is, in the “flat”, scanning is sequentially performed while skipping the line by the “line interval”.

The irradiation control command conversion unit 35 is a functional block that generates an irradiation control command related to electron beam control on the basis of the scan type selected in the scan type selection area 41 and the parameters set in the common parameter setting area 42. The irradiation control command conversion unit 35 generates, for example, elements related to electron beam control in different scanning directions (for example, two directions of X-direction and Y-direction), and converts the elements for each direction into irradiation control commands. Specific examples of the irradiation control command will be described in detail later. The irradiation control command conversion unit 35 transmits the generated irradiation control command to the control block 20. The generated irradiation control command may be stored in a memory (not illustrated) in the management computer 30.

The control block 20 is a functional block that generates a control signal for controlling the electron beam on the basis of the irradiation control command generated by the management computer 30. As illustrated in FIG. 1, the control block 20 includes a memory write control unit 21, a command storage memory 23, and a scan waveform generation unit 25.

The memory write control unit 21 receives, for example, an irradiation control command from the irradiation control command conversion unit 35 and stores the irradiation control command into the command storage memory 23. The memory write control unit 21 can also control each element in the control block 20.

The scan waveform generation unit 25 reads out the irradiation control command stored in the command storage memory 23, and generates a scan waveform on the basis of the irradiation control command as a control signal 26. In this case, the scan waveform generation unit 25 may generate the control signal 26 for each component included in the beam irradiation control device 14. The scan waveform generation unit 25 transmits the generated control signal 26 to the beam irradiation control device 14. The beam irradiation control device 14 controls the irradiation direction of the electron beam on the basis of the control signal 26 received from the scan waveform generation unit 25.

The memory write control unit 21 and the scan waveform generation unit 25 may be realized by executing a program by a processor such as a CPU, or may be configured by an FPGA or an ASIC. The command storage memory 23 may be a non-volatile memory such as a flash memory, or may be a volatile memory such as a static random access memory (SRAM) or dynamic RAM (DRAM) when it is only needed to temporarily store the irradiation control command.

### <Specific Example of Irradiation Control Command and Scan Waveform>

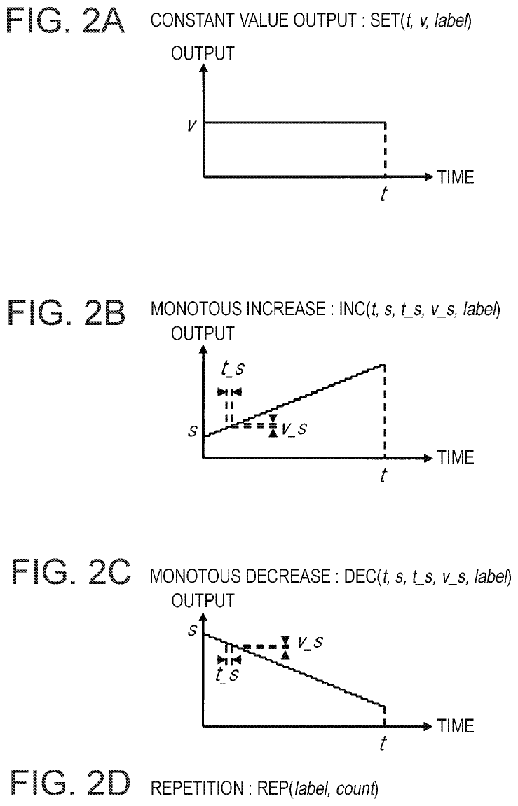

Next, a specific example of the irradiation control command will be described. FIG. 2 is a diagram illustratively describing the irradiation control command and the corresponding scan waveform in comparison with each other. The irradiation control commands are classified into a basic waveform definition command (for example, each command in FIGS. 2(a) to 2(c)) that defines a basic waveform related to the irradiation direction of the electron beam, and a waveform combination command (for example, the command in FIG. 2(d)) that combines waveforms. The scan waveform defined by the basic waveform definition command is different for each command. Further, each basic waveform definition command also specifies parameters for scan waveform adjustment.

FIG. 2(a) illustrates a “SET” command as the basic waveform definition command. The “SET” command is a command that defines a scan waveform that continuously outputs a constant output value for a predetermined time. In the “SET” command, duration t of the scan waveform, an output value v of the scan waveform, and a waveform identification label (label) for identifying the scan waveform are respectively designated as parameters.

FIG. 2(b) illustrates an “INC” command as the basic waveform definition command. The “INC” command is a command that defines a scan waveform whose output value increases each time a predetermined time elapses. In the “INC” command, duration t of the scan waveform that prescribes an initial value of output, an output initial value s, an output value change amount v_s that prescribes a change amount (increase amount) of an output value, an output value change time t_s that prescribes the timing at which the output value changes, and a waveform identification label (label) for identifying the scan waveform are respectively designated as parameters.

As illustrated in FIG. 2(b), the scan waveform generated by the “INC” command is a waveform whose output value continues to increase by the output value change amount v_s each time the output value change time t_s elapses until the duration t elapses when the output is output with the output initial value s.

FIG. 2(c) illustrates a “DEC” command as the basic waveform definition command. The “DEC” command is a command that defines a scan waveform whose output value decreases each time a predetermined time elapses. In the “DEC” command, the duration t of the scan waveform, the output initial value s that prescribes an initial value of output, the output value change amount v_s that prescribes a change amount (decrease amount) of the output value, the output value change time t_s that prescribes the timing at which the output value changes, and the waveform identification label (label) for identifying the scan waveform are respectively designated as parameters.

As illustrated in FIG. 2(c), the scan waveform generated by the “DEC” command is a waveform whose output value continues to decrease by the output value change amount v_s each time the output value change time t_s elapses until the duration t elapses when the output is output with the output initial value s.

FIG. 2(d) illustrates an “REP” command as a waveform combination command. In the “REP” command, the waveform identification label (label) of the scan waveform to be combined and the number of times of repetitions count of the combined scan waveform are designated as parameters. For example, when the “REP” command is executed in the irradiation control command conversion unit 35, a command with the same waveform identification label as that designated by the “REP” command is called, and the called commands are combined. Then, the combined commands are repeated a designated number of times of repetitions. As such, with the “REP” command, a plurality of basic waveform definition commands are combined so as to obtain a desired scan type.

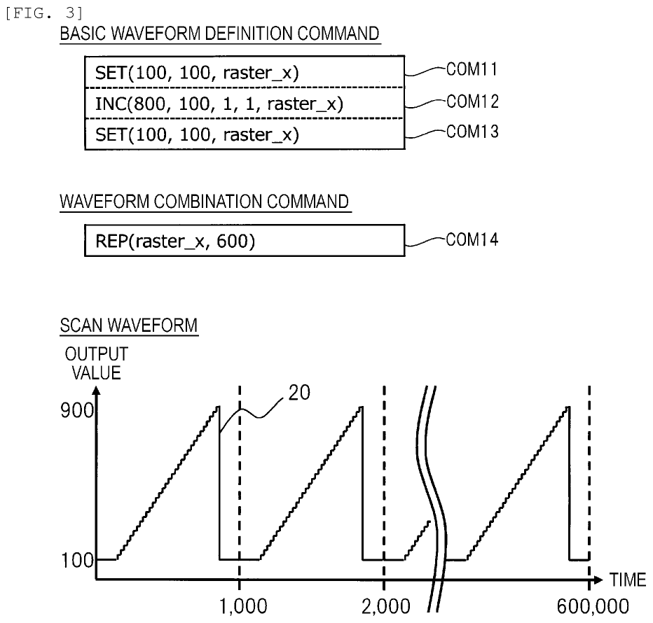

FIG. 3 is a diagram illustratively describing the waveform combination command and the corresponding scan waveform in comparison with each other. FIG. 3 illustrates the irradiation control command in the X-direction and the corresponding scan waveform when realizing a raster scan that scans line by line in comparison with each other. Commands COM11 to COM13 are basic waveform definition commands, and a command COM14 is a waveform combination command.

In the command COM11, the “SET” command is defined. In the command COM11, the duration t=100, the output value v=100, and the waveform identification label (label)=raster_x are respectively designated as parameters.

In the command COM12, the “INC” command is defined. In the command COM12, the duration t=800, the output initial value s=100, the output value change amount v_s=1, the output value change time t_s=1, and the waveform identification label (label)=raster_x are respectively designated as parameters.

In the command COM13, the “SET” command is defined. In the command COM13, the duration t=100, the output value v=100, and the waveform identification label (label)=raster_x are respectively designated as parameters.

In the command COM14, the “REP” command is defined. In the command COM14, the waveform identification label (label)=raster_x and the number of times of repetitions count=600 are respectively designated as parameters.

FIG. 3 illustrates an example of scanning a range having an image size of 800×600. A scan waveform for 800 pixels in the X-direction in each line is defined by the commands COM11 to COM13, and a scan waveform for 600 lines is defined by the command COM14. The command COM13 has the same contents as the command COM11. Therefore, in the command COM14, the same “SET” command may be referred to twice.

The scan waveform of FIG. 3 will be described in detail. First, at a time period 0-100, a scan waveform is generated on the basis of the command COM11 which is the “SET” command. During this period, the output value of the scan waveform is 100. Next, at a time period 100-900, a scan waveform is generated on the basis of the command COM12 which is the “INC” command. During this period, the output value of the scan waveform continues to increase by 1 each time the time elapses by 1. Therefore, when the duration 800 (the time 900) elapses, the output value of the scan waveform is 900. Then, at a time period 900-1000, a scan waveform is generated on the basis of the command COM13 which is the “SET” command. During this period, the output value of the scan waveform is 100. Up to this time point, a scan waveform for one line is generated. Thereafter, up to the time 600,000, the same scan waveform is generated for 600 lines.

In this way, by combining the basic waveform definition command and the waveform combination command, the number of commands needed to realize the raster scan is reduced. Actually, a scan waveform that controls the Y-direction may be generated separately.

The irradiation control command conversion unit 35 generates the irradiation control command on the basis of the selected scan type and each specified scan parameter, but for making the generation of irradiation control command efficient, the basic waveform definition command and the waveform combination command may be templated for each scan type in advance.

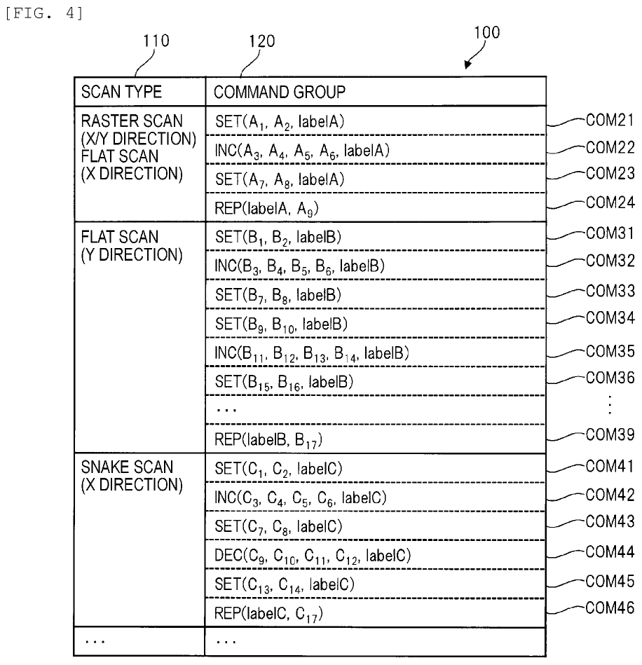

FIG. 4 is a diagram illustrating an example of a command template. A command template 100 includes a scan type column 110 indicating the scan types and a command column 120 indicating commands to be executed for each scan type.

For example, commands COM21 to COM24 correspond to the “raster” scan and “flat” scan in the X-direction. The commands COM21 to COM23 are basic waveform definition commands, and the command COM24 is the waveform combination command. A1 to A9 and label A in the commands COM21 to COM24 are parameters of respective commands.

Further, for example, commands COM31 to COM36, COM39 correspond to the “flat” scan in the Y-direction. The commands COM31 to COM36 and the like are basic waveform definition commands, and the command COM39 is the waveform combination command. B1 to B17, label B, and the like in the commands COM31 to COM36 and COM39 are parameters.

Further, for example, commands COM41 to COM46 correspond to the “snake” scan in the X-direction. The commands COM41 to COM45 are basic waveform definition commands, and the command COM46 is the waveform combination command. C1 to C17 and label C in the commands COM41 to COM46 are parameters.

FIG. 4 is just an example, and the command template is not limited to FIG. 4. The user can appropriately create any command template in order to realize a desired scan type. Further, a command template different from that in FIG. 4 may be separately prepared for the same scan type. These command templates are stored in, for example, a memory (not illustrated) in the management computer 30.

When the command template is used, if the scan type is selected by the user, the irradiation control command conversion unit 35 refers to the command template 100 and reads out each command corresponding to the selected scan type from the memory. Then, the irradiation control command conversion unit 35 generates an irradiation control command by applying the scan parameter designated by the user to the read command.

### <Processing After Electron Beam Irradiation>

The scan waveform generation unit 25 generates a control signal which is a scan waveform on the basis of the irradiation control command and transmits the control signal to the beam irradiation control device 14. When irradiated with an electron beam, an SEM image is generated. In that case, various information such as parameters set by the user may be displayed on the generated SEM image. With this configuration, the set parameters can be linked with an acquired image. Alternatively, data of the SEM image and various information such as parameters may be stored in association with each other.

<Main Effects of this Embodiment>

According to this embodiment, the irradiation control command conversion unit 35 and the management computer generate the irradiation control command on the basis of the scan type selected by the user and the scan parameters set by the user. Then, the scan waveform generation unit 25 generates the control signal on the basis of the irradiation control command.

According to this configuration, since the scan waveform can be set without changing a device configuration, it is possible to observe the sample under the desired scan condition while suppressing an increase in TAT.

Further, according to this embodiment, the irradiation control command conversion unit 35 generates the irradiation control command for each scanning direction of the electron beam. According to this configuration, it is possible to simplify the irradiation control command.

Further, according to this embodiment, the irradiation control command conversion unit 35 generates the irradiation control command by combining basic waveform definition commands that define basic waveforms with the waveform combination command. The basic waveform definition command includes a command that defines a control signal that continuously outputs a constant output value for a predetermined time. Further, the basic waveform definition command includes a command that defines a control signal whose output value increases each time a predetermined time elapses. Further, the basic waveform definition command includes a command that defines a control signal whose output value decreases each time a predetermined time elapses. According to this configuration, it is possible to suppress an increase in the number of basic waveform definition commands needed.

The management computer 30 stores the command template 100 in which the basic waveform definition commands and the waveform combination command are templated for each scan type. According to this configuration, when the irradiation control command is generated, since it is not needed to calculate the combination of the basic waveform definition commands by computation, the load related to the generation of the irradiation control command is reduced.

The management computer 30 displays the GUI screen 40 that receives an input operation by the user. According to this configuration, the user can select the scan type and set the scan parameters while looking at the GUI screen 40.

### Embodiment 2

In the following embodiment, a case where the scan waveform is set directly on the GUI screen 40 will be described. First, in Embodiment 2, for example, the scan waveform in the X-direction (first direction) is directly set. In the following, descriptions will be omitted in principle for the parts that overlap with the embodiment described above.

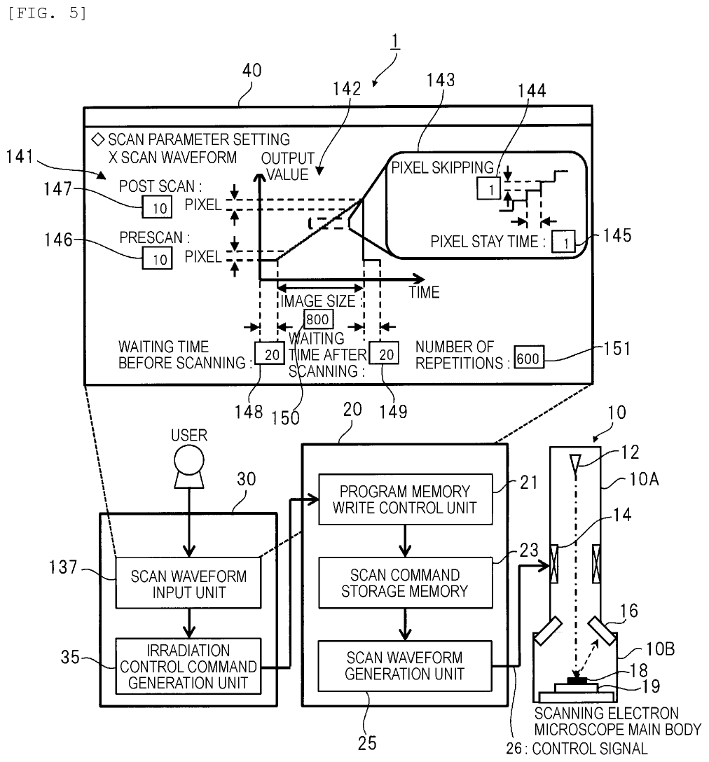

FIG. 5 is a diagram illustrating an example of a configuration of a scanning electron microscope according to Embodiment 2 of the present invention. In this embodiment, the configuration of the management computer 30 is different from that in FIG. 1. The management computer 30 of FIG. 5 includes a scan waveform input unit 137 and the irradiation control command conversion unit 35. The scan waveform input unit 137 is a functional block that performs input processing of the scan waveform set on the GUI screen 40 illustrated in FIG. 5, for example. The scan waveform input unit 137 is realized by executing a program by a processor such as a CPU. Further, the scan waveform input unit 137 may be configured by hardware such as an FPGA or ASIC, or may be configured by combining hardware and software.

The GUI screen 40 of FIG. 5 receives an input operation related to setting of the scan waveform by the user. On the GUI screen 40, a scan waveform setting screen is graphically displayed. The GUI screen 40 includes a scan waveform setting area (first scan waveform setting area) 141 in which a scan waveform in one direction can be set.

The scan waveform setting area 141 includes a scan waveform display area 142 for displaying a scan waveform for setting, and a scan waveform enlarged display area 143 for displaying a part of the scan waveform in an enlarged manner. As illustrated in FIG. 5, the scan waveform enlarged display area 143 includes parameter setting areas 144 and 145. In the parameter setting area 144, for example, a pixel skipping amount in the X-direction at the time of scanning is set. In the parameter setting area 145, for example, the pixel stay time per pixel is set.

The scan waveform display area 142 includes parameter setting areas 146 to 151. In the parameter setting area 146, the number of pixels for pre-scanning is set. In the parameter setting area 147, the number of pixels for post-scanning is set. In the parameter setting area 148, the waiting time before scanning is set. In the parameter setting area 149, the waiting time after scanning is set. In the parameter setting area 150, the number of pixels for scanning is set. For example, if the number of pixels in one line is 800, “800” is set in the parameter setting area 150 as illustrated in FIG. 5. In the parameter setting area 151, the number of times of repetitions of scanning in the X-direction is set. For example, when scanning 600 lines, “800” is set in the parameter setting area 150.

The user can easily set the scan waveform by inputting each parameter of the scan waveform while looking at the scan waveform setting area 141 of the GUI screen 40.

The scan waveform input unit 137 transmits each parameter input from the GUI screen 40 to the irradiation control command conversion unit 35. The irradiation control command conversion unit 35 generates an irradiation control command on the basis of each parameter received from the GUI screen 40. The parameters input to the scan waveform input unit 137 are parameters of the irradiation control command. Therefore, the irradiation control command conversion unit 35 can generate the irradiation control command only by converting these parameters into an irradiation control command format. That is, the irradiation control command conversion unit 35 generates the irradiation control command on the basis of the scan waveform set by the user. Since processing after the irradiation control command is generated is the same as that of Embodiment 1, the rest of description thereof will be omitted below.

According to this embodiment, the irradiation control command conversion unit 35 generates the irradiation control command on the basis of the scan waveform set by the user. According to this configuration, the user can intuitively and easily set the scan waveform freely. Further, it is possible to easily acquire an image under arbitrary scanning conditions.

Further, according to this embodiment, the GUI screen 40 includes the scan waveform setting area 141 in which the scan waveform in the X-direction can be set. According to this configuration, it is possible to suppress the complexity of the GUI screen 40 and to comfortably set the scan waveform.

### Embodiment 3

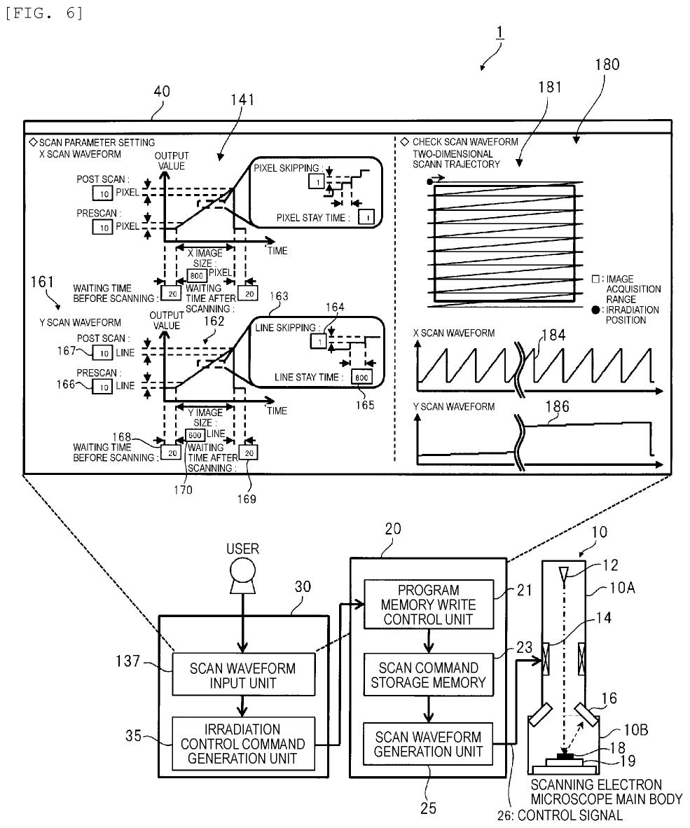

Next, Embodiment 3 will be described. In Embodiment 3, the scan waveform for two directions is directly set. FIG. 6 is a diagram illustrating an example of a configuration of a scanning electron microscope according to Embodiment 3 of the present invention. The device configuration of FIG. 6 is the same as that of FIG. 5 except for the configuration of the GUI screen 40.

The GUI screen 40 includes, for example, the scan waveform setting area 141 in which the scan waveform in the X-direction can be set, and a scan waveform setting area (second scan waveform setting area) 161 in which a scan waveform in the Y-direction can be set. In this way, in this embodiment, two scan waveform setting areas 141 and 161 in which the scan waveforms in the X-direction and the Y-direction (second direction different from the first direction) can be set are displayed side by side.

The scan waveform setting area 161 includes a scan waveform display area 162 for displaying a scan waveform for setting in the Y-direction, and a scan waveform enlarged display area 163 for displaying a part of the scan waveform in the Y-direction in an enlarged manner. As illustrated in FIG. 6, the scan waveform enlarged display area 163 includes parameter setting areas 164 and 165. In the parameter setting area 164, for example, a line skipping amount in the Y-direction at the time of scanning is set. In the parameter setting area 165, the one-line stay time at the time of scanning is set. That is, in the parameter setting area 165, the scan time required for one line is set.

The scan waveform display area 162 includes parameter setting areas 166 to 170. In the parameter setting area 166, the number of lines for pre-scanning is set. In the parameter setting area 167, the number of lines for post-scanning is set. In the parameter setting area 168, the waiting time before scanning is set. In the parameter setting area 169, the waiting time after scanning is set. In the parameter setting area 170, the number of lines for scanning is set. For example, when scanning for 600 lines, “600” is set in the parameter setting area 170 as illustrated in FIG. 6.

Further, the GUI screen 40 includes a scan waveform check area 180. The scan waveform check area 180 includes a scan trajectory check area 181, a scan waveform display area (first scan waveform display area) 184, and a scan waveform display area (second scan waveform display area) 186.

The scan trajectory display area 181 is an area for displaying a two-dimensional scan trajectory. The scan trajectory display area 181 may display a scan trajectory with a still image as illustrated in FIG. 6, or may display a scan trajectory with a moving image that moves the irradiation position of the electron beam.

The scan waveform display area 184 is an area for displaying the scan waveform (first scan waveform) in the X-direction set in the scan waveform setting area 141. The scan waveform display area 186 is an area for displaying the scan waveform (second scan waveform) in the Y-direction set in the scan waveform setting area 161. In this way, in this embodiment, the scan waveforms in the X-direction and the Y-direction are displayed side by side.

The user can easily set the scan waveform by inputting each parameter of the scan waveform while looking at the scan waveform setting areas 141 and 161 and the scan waveform check area 180 on the GUI screen 40.

The scan waveform setting areas 141 and 161 and the scan waveform check area 180 may be displayed on a separate screen. For example, when the scan waveform setting areas 141 and 161 are displayed on the GUI screen 40, a display changeover switch to the scan waveform check area 180 may be displayed. Contrary to this, when the scan waveform check area 180 is displayed on the GUI screen 40, the display changeover switch to the scan waveform setting areas 141 and 161 may be displayed.

According to this embodiment, the GUI screen 40 includes the scan waveform setting area 141 in which the scan waveform in the X-direction can be set, and the scan waveform setting area 161 in which the scan waveform in the Y-direction can be set.

If the scan parameters in the X- and Y-directions are input on separate screens, it is difficult to grasp the image of the entire trajectory, but according to the GUI screen 40 of this embodiment, it is possible to input scan parameters in the X-direction and the Y-direction and check the input results at the same time.

Further, according to this embodiment, the GUI screen 40 includes the scan waveform display area 184 corresponding to the scan waveform setting area 141 and the scan waveform display area 186 corresponding to the scan waveform setting area 161. According to this configuration, since the set scan parameters and the scan waveform are displayed at the same time, the image of the scan waveform can be easily grasped.

Further, according to this embodiment, the GUI screen 40 includes the scan trajectory display area 181 for displaying a two-dimensional scan trajectory. According to this configuration, since the scan trajectory is visualized, the scan trajectory can be easily set.

Further, instead of the scan waveforms in the X-direction and Y-direction, it is also possible to compute coordinate information from the scan waveforms in the X-direction and Y-direction and draw the scan position (electron beam irradiation position) in a two-dimensional plane for each time. In this case, the scan position may be displayed in the scan trajectory display area 181 of FIG. 6. With this configuration, the user can easily grasp the scanning trajectory in the XY-plane.

The present invention is not limited to the embodiments described above, and includes various modifications made thereto. Further, it is possible to replace a part of a configuration of one embodiment with a configuration of another embodiment, and it is also possible to add a configuration of another embodiment to a configuration of one embodiment. For a part of the configuration of each embodiment, other configurations can be added, deleted, or replaced. Each member and relative size described in the drawings are simplified and idealized in order to explain the present invention in an easy-to-understand manner, and may have a more complicated shape in implementation.

### REFERENCE SIGNS LIST

1: scanning electron microscope

10: scanning electron microscope main body

14: beam irradiation control device

20: control block

21: memory write control unit

23: command storage memory

25: scan waveform generation unit

26: control signal

30: management computer

31: scan type selection unit

33: scan parameter input unit

35: irradiation control command conversion unit

40: GUI screen

41: scan type selection area

42: common parameter setting area

43: individual parameter setting area

141, 161: scan waveform setting area

180: scan waveform check area

181: scan trajectory display area

184, 186: scan waveform display area

1.-14. (canceled)

15. A scanning electron microscope comprising:
a management computer that generates an irradiation control command of an electron beam;
a control block that generates a control signal on the basis of the irradiation control command; and
a beam irradiation control device that controls an irradiation direction of the electron beam on the basis of the control signal, wherein
the management computer generates the irradiation control command on the basis of a scan type selected by a user and scan parameters set by the user.

16. The scanning electron microscope according to claim 15, wherein
the management computer generates the irradiation control command for each scanning direction of the electron beam.

17. The scanning electron microscope according to claim 15, wherein
the management computer generates the irradiation control command by combining a basic waveform definition command that defines a basic waveform with a waveform combination command.

18. The scanning electron microscope according to claim 17, wherein
the basic waveform definition command includes a command that defines the control signal for continuously outputting a constant output value for a predetermined time.

19. The scanning electron microscope according to claim 17, wherein
the basic waveform definition command includes a command that defines the control signal whose output value increases each time a predetermined time elapses.

20. The scanning electron microscope according to claim 17, wherein
the basic waveform definition command includes a command that defines the control signal whose output value decreases each time a predetermined time elapses.

21. The scanning electron microscope according to claim 17, wherein
the management computer stores a command template in which the basic waveform definition command and the waveform combination command are templated for each scan type.

22. A scanning electron microscope comprising:
a management computer that generates an irradiation control command of an electron beam;
a control block that generates a control signal on the basis of the irradiation control command; and
a beam irradiation control device that controls an irradiation direction of the electron beam on the basis of the control signal, wherein
the management computer generates the irradiation control command on the basis of a scan waveform set by a user.

23. The scanning electron microscope according to claim 22, wherein
the management computer displays an input screen that receives an input operation related to setting of the scan waveform by the user.

24. The scanning electron microscope according to claim 23, wherein
the input screen includes a first scan waveform setting area in which the scan waveform in a first direction is set.

25. The scanning electron microscope according to claim 24, wherein
the input screen includes a second scan waveform setting area in which the scan waveform in a second direction different from the first direction is set.

26. The scanning electron microscope according to claim 25, wherein
the input screen includes a first scan waveform display area for displaying a first scan waveform set in the first scan waveform setting area, and a second scan waveform display area for displaying a second scan waveform set in the second scan waveform setting area.

27. The scanning electron microscope according to claim 25, wherein
the input screen includes a scan trajectory display area for displaying a two-dimensional scan trajectory.
